(19) United States
(12) Patent Application Publication
(10) Pub. No.: US 2025/0208178 A1
(43) Pub. Date: Jun. 26, 2025

(54) Dimensional Metering of Consumer Electrical Power

(71) Applicant: Casey Shull, Fountaintown, IN (US)

(72) Inventor: Casey Shull, Fountaintown, IN (US)

(21) Appl. No.: 18/990,002

(22) Filed: Dec. 20, 2024

Related U.S. Application Data
(60) Provisional application No. 63/613,324, filed on Dec. 21, 2023.

(51) Int. Cl. G01R 22/06; G06Q 50/06

(52) U.S. Cl. CPC G01R 22/063; G06Q 50/06

(57) ABSTRACT

A method to discretely meter consumption of electricity includes embedding a discrete signal at a source of electrical production associated with each type of power production; and consumption metering at a consumption location that determines the type of electrical production being consumed from the discrete signal.

### CROSS REFERENCE TO RELATED APPLICATION[S]

The present disclosure claims priority to United States Provisional Patent Disclosure Ser. No. 63/613,324 (02092-SHUL) filed Dec. 21, 2023.

### BACKGROUND

The present disclosure relates to electrical power distribution

The consumer electrical system is primarily composed of electrical production, electrical transmission, distribution, and consumption. The consumption is measured in Kilowatt hours (kWh) consumed. A method to determine consumption is amps X voltage=kW over time or per hour which equals the kWh. The definition can be thought of as how many kW are being consumed per hour.

Methods of electrical production use fuel such as coal, diesel, natural gas, or nuclear fission to produce steam to drive a turbine. Typically, solar power plants, wind turbine power plants, and hydroelectric power plants are described as renewables.

The methods of electrical production are combined or joined into one frequency or sine wave on a transmission line to transmit to consumers. Combining all electrical production sources into one sine wave is unavoidable since the resultant output of the production of electricity is combined into one sine wave regardless of the source. The total amount of available electricity produced cannot be segregated into component methods of production. Thus, electric utilities and consumers cannot determine which electrical production source is being consumed. The metering facilities cannot segregate each individual source of power production.

If consumers want to purchase a specific type of electrical production, there are currently no methods to determine which electrical source of power production is being consumed. In other words, if a consumer wants to purchase 100% renewable energy, the current methods of metering cannot determine which source produced the electricity being consumed.

### SUMMARY

A method to discretely meter consumption of electricity according to one disclosed non-limiting embodiment of the present disclosure includes embedding a discrete signal at a source of electrical production associated with each type of power production; and consumption metering at a consumption location that determines the type of electrical production being consumed from the discrete signal.

A further embodiment of any of the foregoing embodiments of the present disclosure includes embedding a Broadband over Power line (BPL) as the discrete signal.

A further embodiment of any of the foregoing embodiments of the present disclosure includes applying a Nash Equilibrium (NE) at the consumption location to identify the sources of power production.

A further embodiment of any of the foregoing embodiments of the present disclosure includes applying the Nash Equilibrium (NE) at the consumption location using Networked Cournot Competition to identify the sources of power production.

A further embodiment of any of the foregoing embodiments of the present disclosure includes that each discrete broadband signal will identify a specific source of the electrical production within a single sine wave used to create the identifier or create an embedded discrete signal at the source of electrical production. Then BPL allows the identification of the discrete signals at the source of consumption.

A further embodiment of any of the foregoing embodiments of the present disclosure includes wherein a sine wave from each source of electrical production are aggregated into one single sine wave.

A further embodiment of any of the foregoing embodiments of the present disclosure includes that the sine wave is not divided into component parts.

A further embodiment of any of the foregoing embodiments of the present disclosure includes differentiating rate structures based upon type of electrical production.

A further embodiment of any of the foregoing embodiments of the present disclosure includes segregating the consumption based upon the identified type of electrical production consumed at the consumption location.

A method to discretely meter consumption of electricity according to one disclosed non-limiting embodiment of the present disclosure includes embedding a discrete sine wave signal at a source of electrical production associated with each type of power production; and consumption metering at a consumption location that determines the type of electrical production being consumed from the discrete sine wave.

The foregoing features and elements may be combined in various combinations without exclusivity, unless expressly indicated otherwise. These features and elements as well as the operation thereof will become more apparent in light of the following description and the accompanying drawings. It should be appreciated that however the following description and drawings are intended to be exemplary in nature and non-limiting.

### BRIEF DESCRIPTION OF THE DRAWINGS

Various features will become apparent to those skilled in the art from the following detailed description of the disclosed non-limiting embodiment. The drawings that accompany the detailed description can be briefly described as follows:

FIG. 1 is a schematic view of a dimensional metering system according to one disclosed non-limiting embodiment.

### DETAILED DESCRIPTION

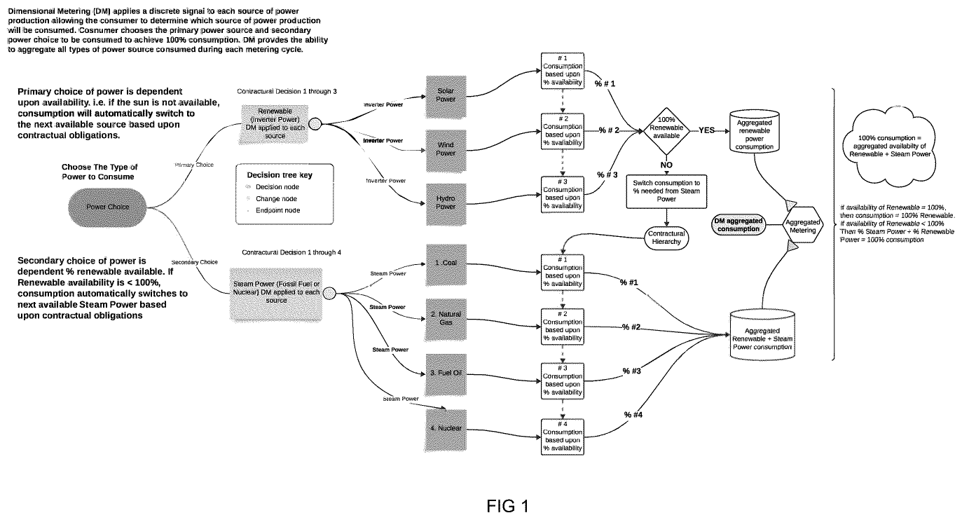

FIG. 1 schematically illustrates a system and method to determining the type of electrical production being consumed, which is defined herein as “dimensional metering”. Dimensional metering provides a system and method to embed a discrete signal linked to each type of power production. This signal enables consumption metering to identify the type of electrical production being consumed and determine the amount available for consumption.

If consumers closest to the electrical production source utilize 100% of the available resource, a consumer wanting to utilize the same type of electrical production will consume and be metered for the other sources available. The regulators, electric utilities, and electrical producers will be able to adjust the rate structure based upon actual type of electrical production being consumed. For example: If the total amount of electrical production available is 100 megawatts (MW) that is divided into 60 MW steam turbine, 20 MW Solar, and 20 MW wind. If a consumer wants to consume 100% renewable but renewable is not available due to production or consumption of the other consumers, the consumer wanting renewable energy will consume steam turbine generated electricity. The type of electricity being consumed can be developed into a different cost structure. The resultant invoice to the consumer will reflect the various types of electrical production that was consumed during the billing period.

The dimensional metering system identifies the type of power from each production facility, steam generator, solar, wind, and/or additional facilities such as hydro and others. The total electrical power output is identified by a frequency or sine wave. The sine wave is a measure, or frequency, of the amplitude and the amount of time required for the sine wave to cross over the x-axis into the negative quadrant and back to the point of intersecting the x-axis prior to re-entering the positive quadrant. The measurement, or frequency, over the course of 60 combined crossings in one second is considered one cycle. In the United States, the frequency is measured as 60 Hz. Or the resultant single cycle, in the United States, is measured in 60 cycles per second.

Sine waves from different sources eventually aggregate into one single sine wave. That is, aggregated onto an electrical transmission line typically at an electrical transmission substation where each electrical transmission line intersects and aggregated into one electrical sine wave.

Steam turbines, renewables and other sources of electrical production are combined into the one single sine wave. Dimensional metering does not “split” the sine wave back into its component parts that have aggregated into one sine wave but provides a discrete broadband signal embedded within the electrical sine wave. After the aggregation of the electrical production into one sine wave, the electrical sine wave becomes the carrier for all of the discrete communication RF signals created at each electrical production source. Multiple RF signals, representing each power production source, can be placed onto an electrical conductor/inserted into the sine wave using frequency-division multiplexing (FDM).

Discrete metering identifies each source with a discrete signal so the quantity of each source can be identified. Dimensional metering provides the ability to identify each individual source of power production. e.g., is the purchased electricity from wind, solar, hydro, or coal-fired steam power plants. Dimensional metering discretely identifies each individual source and quantity of electrical production at the source of production. The discrete identifiers will remain embedded within the aggregated sine wave. The consumer electrical metering will be able to identify each discrete signal allowing the consumer to segregate the type of power production consumed.

Dimensional metering may utilize Broadband over Power line (BPL) at the source and Nash Equilibrium (NE) at the consumption location.

Broadband over Power line (BPL) is used to create the identifier or create an embedded discrete signal at the source of electrical production. Then BPL allows the identification of the discrete signals at the consumption location.

Nash Equilibrium (NE) applied as (congestion control) or Competitive Routing Over Networks. NE is applied at the consumption location using, for example, Networked Cournot Competition to identify the sources of power production.

The discrete signal is applied at the source of power production using BPL. For example, the following discrete signals may be applied at the source: U—utility (steam power plant); S—Solar; W—Wind, identified as embedded in the aggregated sine wave. It should be appreciated that this is merely an example, and any unique discrete signal may be applied at the source of power production using BPL to identify the source.

Each discrete broadband signal will identify the specific source of electrical production within a single sine wave. The discrete signal is embedded within the electrical sine wave using FDM on the transmission system that is distributed to consumers. Ultimately there can be N-production (players that are providing electrical production I={1, . . . ,N}) competing over L spatially distributed markets denoted as consumers. The resultant system is an electrical sine wave with embedded broadband signals which are discrete identifiers of the electrical production source. The embedded signals available can be aggregated as additional sources of electrical production. In other words, if there are multiple production sources aggregated into transmission lines, the electrical production will be aggregated into a single sine wave with discrete RF signals as the sources are available to produce electricity. As the sources are consumed, the resultant proportions are calculated to determine the availability of specific type of sources available to ‘downstream’ consumers.

The electrical sine wave is not divided into component parts, but the discrete signals provide the proportioned availability of specific sources of electrical production to consumers. The consumption meters identify each discrete signal indicative of specific electrical production consumed, allowing the consumption invoice to identify segregated types of electrical consumption. The rate structure will be differentiated based upon the type of electrical production, the consumption will be segregated based upon the identified type of electrical production consumed. When the consumer pays the electrical bill, the process begins again for the next billing cycle.

Dimensional metering is an innovative method of identifying different types of electrical production by assigning a discrete communication signal to each type of electrical production. The discrete signal will be inserted onto the electrical line from the electrical production source. All electrical production is aggregated into one sine wave and onto a single transmission or distribution conductor. Each discrete identifying communication signal are simultaneously inserted onto the transmission or distribution line using the electrical sine wave as the carrier for all of the different discrete communication signals. The result allows consumers to identify which source of electrical production is desirable to consume. Thus, the consumer can choose which type of electrical production they prefer to utilize in the transactive process of kilowatt hour consumption.

Although the different non-limiting embodiments have specific illustrated components, the embodiments of this invention are not limited to those particular combinations. It is possible to use some of the components or features from any of the non-limiting embodiments in combination with features or components from any of the other non-limiting embodiments.

The foregoing description is exemplary rather than defined by the limitations within. Various non-limiting embodiments are disclosed herein, however, one of ordinary skill in the art would recognize that various modifications and variations in light of the above teachings will fall within the scope of the appended claims. It is therefore to be appreciated that within the scope of the appended claims, the disclosure may be practiced other than as specifically described. For that reason the appended claims should be studied to determine true scope and content.

What is claimed is:

1. A method to discretely meter consumption of electricity, comprising:
embedding a discrete signal at a source of electrical production associated with each type of power production; and
consumption metering at a consumption location that determines the type of electrical production being consumed from the discrete signal.

2. The method as recited in claim 1, further comprising:
embedding a Broadband over Power line (BPL) as the discrete signal.

3. The method as recited in claim 2, further comprising:
applying a Nash Equilibrium (NE) at the consumption location to identify the sources of power production.

4. The method as recited in claim 3, further comprising:
applying the Nash Equilibrium (NE) at the consumption location using Networked Cournot Competition to identify the sources of power production.

5. The method as recited in claim 4, wherein each discrete broadband signal will identify a specific source of the electrical production within a single sine wave used to create the identifier or create an embedded discrete signal at the source of electrical production. Then BPL allows the identification of the discrete signals at the source of consumption.

6. The method as recited in claim 5, wherein a sine wave from each source of electrical production are aggregated into one single sine wave.

7. The method as recited in claim 6, wherein the sine wave is not divided into component parts.

8. The method as recited in claim 7, further comprising:
differentiating rate structures based upon type of electrical production.

9. The method as recited in claim 8, further comprising:
segregating the consumption based upon the identified type of electrical production consumed at the consumption location.

10. A method to discretely meter consumption of electricity, comprising:
embedding a discrete sine wave signal at a source of electrical production associated with each type of power production; and
consumption metering at a consumption location that determines the type of electrical production being consumed from the discrete sine wave.
